(19) United States
(12) Patent Application Publication
(10) Pub. No.: US 2008/0279311 A1
(43) Pub. Date: Nov. 13, 2008

(54) AD Converter Bandwidth Enhancement Using An IQ Demodulator And Low Frequency Cross-Over Network

(76) Inventor: Roger Lee Jungerman, Petaluma, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/745,224

(22) Filed: May 7, 2007

(51) Int. Cl. H03D 1/24

(52) U.S. Cl. 375/321; 375/E07.041

(57) ABSTRACT

A low frequency cross-over network is added to a DC coupled IQ demodulator. The low frequency data can be captured in a very accurate, low cost, low bandwidth DC coupled path with ˜40 MHz of bandwidth. The remaining bandwidth (up to 20 or more GHz) can be captured with the IQ demodulator feeding the high speed ADCs.

### BACKGROUND

Time interleaved A/D converters are commonly used to increase the bandwidth and sample rate of the conversion. Track-hold circuits with a narrow sampling aperture can be placed in front of the A/D converters. Several converters are placed in parallel with slight delays between the acquisition clock to the track holds. Thus, several time interleaved samples can be obtained (TDI), where the time delay between the successive samples is less than the aperture time of the track-hold, e.g. 1/bandwidth. Typically, as the sampling aperture of a track-hold that preceded the converter is reduced, the dynamic range and voltage resolution of the track/hold and hence the conversion is degraded. Since the dynamic range of the A/D is low, a variable gain amplifier is required before the track/hold. This DC coupled variable gain amplifier is a complex design.

Mixers are commonly used to down-convert narrow-band RF signals to a lower frequency IF. These mixers are used in both radio systems as well as in spectrum analyzer measurement equipment. The dynamic range of the mixer greatly exceeds the dynamic range of a multi-GS/s ADC.

A specialized type of mixer, IQ demodulator, may be used to produce two low frequency quadrature outputs. With proper calibration, it is possible to separately digitize the IQ demodulator outputs to achieve twice the aggregate digitized bandwidth, while each ADC operates at half the aggregate rate.

IQ demodulators (shown in FIG. 1) are typically AC coupled on the RF in ports. Using large value AC coupling capacitors, the low frequency cut-of can be pushed down to low frequency values. To illustrate, a 20 GHz IQ demodulator can be designed with a low frequency cut-off of 40 MHz. It is possible to design a DC coupled high bandwidth IQ demodulator with considerable complexity. To illustrate, GaAs is used for microwave IQ demodulators but the process is not suitable for DC operation due to very poor 1/f noise.

### SUMMARY

A low frequency cross-over network is added to a DC coupled IQ demodulator. The low frequency data can be captured in a very accurate, low cost, low bandwidth DC coupled path with ˜40 MHz of bandwidth. The remaining bandwidth (up to 20 or more GHz) can be captured with the IQ demodulator feeding the high speed ADCS.

### BRIEF DESCRIPTION OF THE DRAWINGS

FIG. 1 illustrates a typical IQ demodulator.

FIG. 2 illustrates a low-frequency cross-over network to be used with an IQ demodulator.

### DETAILED DESCRIPTION

The invention uses a low frequency cross-over network to circumvent the problem of a DC coupled IQ demodulator. The low frequency data can be captured in a very accurate, low cost, low bandwidth DC coupled path with ˜40 MHz of bandwidth. Integrated ADCs and DC coupled front-end amplifiers are commonly available. The remaining bandwidth (up to 20 or more GHz) can be captured with the I Q demodulator feeding the high speed ADCS.

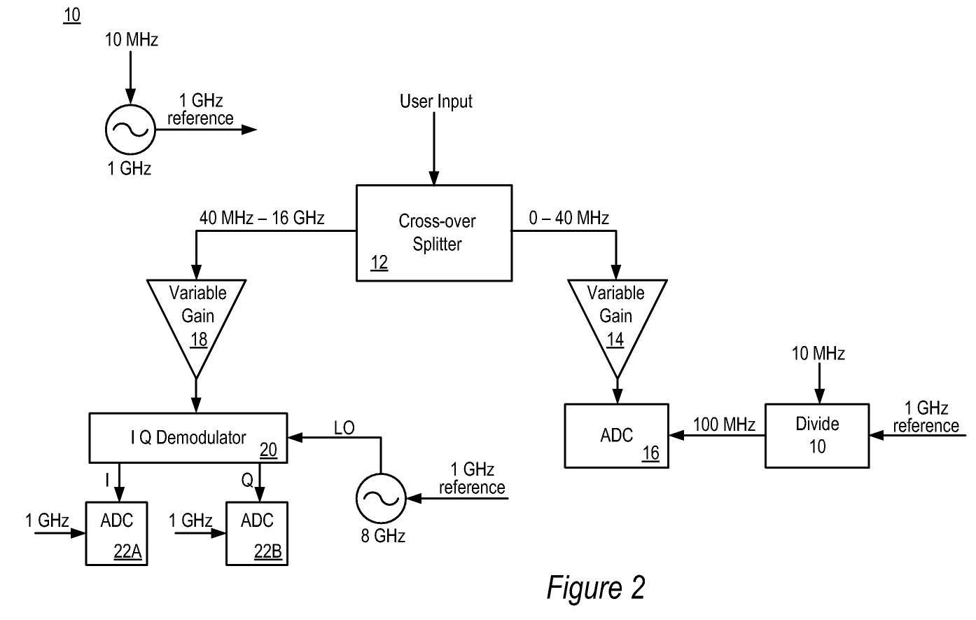

The phase of the local oscillator (LO) into the IQ demodulator must be known relative to the clocks to the ADCS. FIG. 2 illustrates an embodiment where all clocks are at multiples of a low frequency reference. In this case high speed ADC 22A and 22B each consist of multiple time interleave ADCs operating at a rate of 1 GHz. The effective aggregate sample rate of each ADC is 20 GS/s. Obtaining higher sample rates by further time interleaving can be challenging, due to the exceptionally tight timing tolerances required. All the other higher frequency clocks are at integer multiples of this 1 GHz reference frequency and phase locked to the low frequency, 10 MHz, reference. The ADC acquisition is initiated synchronous with the low frequency reference. This approach is functionally equivalent to deriving the higher frequency references by multiplying up the low frequency reference, but typically has lower phase noise.

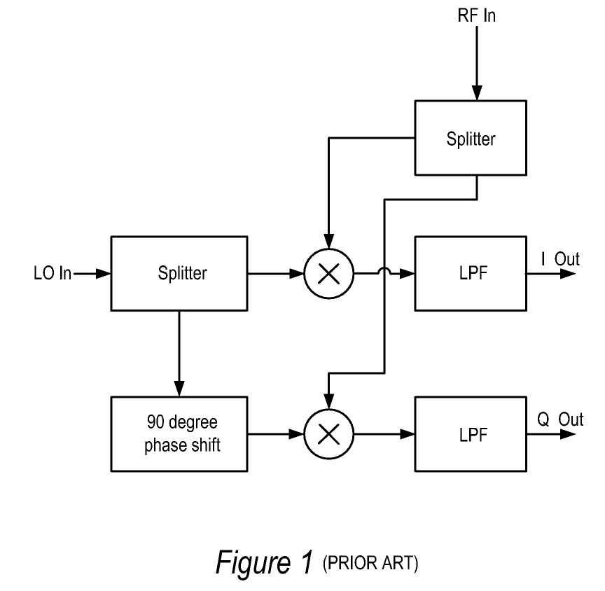

A cross over splitter 12 has a high frequency output and a low frequency output. The low frequency output is received by a first variable gain amplifier 14. A first ADC 16 receives the output of the first variable gain amplifier 14 and a first reference signal. The high frequency output is received by a second variable gain amplifier 18. An IQ demodulator 20 receives the output of the second variable gain amplifier 18 and a second reference signal. The I and Q outputs of the IQ demodulator 20 are each respectively connected to an ADC 22A, 22B. The system in FIG. 1 achieves an effective sample rate of 40 GS/s.

This basic IQ demodulator block with the variable gain amplifier and splitter (assuming the gain is set so that the total gain is unity—from user input to high frequency ADC input) is easily cascadable. Only a single low frequency ADC is required. All the DC and low frequency information in the signal are obtained from the single low frequency ADC. All the IQ demodulators are AC coupled. For each stage of IQ demodulator, an additional pair of high frequency ADCs are required. For a two-stage implementation comparable to the embodiment shown in FIG. 2, the circuit would include 3 IQ demodulators and splitters, a single low frequency ADC, and 4 high frequency ADCs.

The LO for the second stage 1Q demodulator can be obtained with a simple divide by 2 prescaler (the start-up phase of the prescaler must be measured). An aggregate bandwidth of 32 GHz at an effective sample rate of 80 GS/s is produced (assuming an I Q demodulator with sufficient bandwidth is available).

The total amount of digital data required from the low frequency ADC is relatively small compared the high frequency ADCs. In the aforementioned example (FIG. 1), 40 billion samples of high-speed ADC data are stored to memory for every 100 million samples of low-speed ADC data. With modern deep memory digitizers that employ DRAM memories running at a higher clock rate together with a FIFO in the digital system (often a FPGA), inserting this slow speed ADC data into the existing high speed data stream can be accommodated with only an insignificant increase in DRAM overhead. A major redesign of the memory architecture is not required to accommodate the low-frequency crossover data and the total memory depth of the product (in terms of the number samples) will not be changed significantly.

Many common applications for IQ demodulators in communication systems require 60 or more dB of dynamic range. When using devices such as these for high bandwidth real-time oscilloscope applications, the requirements are significantly relaxed. To illustrate, to achieve distortion performance equivalent to 8-bits, only 48 dB of dynamic range is required. The data from the low-frequency ADCs can be stored along with the fast ADC data to calculate the reconstructed waveform in software. Alternatively, the slow ADC data can be used to correct the fast ADC data as it is acquired and stored to memory.

I claim:

1. A circuit comprising:
a low frequency crossover network having a low frequency output and a high frequency output;
a first variable gain amplifier receiving the low frequency output;
a second variable gain amplifier receiving the high frequency output;
a first analog to digital converter, receiving the output of the first variable gain amplifier and a first reference signal, capturing low frequency data;
an IQ demodulator, receiving the output of the second variable gain amplifier and a second reference signal, having an I output and a Q output;
a second analog to digital converter receiving the I output; and
a third analog to digital converter receiving the Q output;
wherein the second and third analog to digital converters capture time-interleaved high frequency data.

2. A circuit, as in claim 1, wherein the first and second reference signals are integer multiples of a low frequency reference source.
